(19) United States
(12) Patent Application Publication
(10) Pub. No.: US 2012/0074506 A1
(43) Pub. Date: Mar. 29, 2012

(54) Semiconductor Package for Higher Power Transistors

(75) Inventors: Andrew Shabalin, Fort Collins, CO (US); Courtney Crandell, Fort Collins, CO (US)

(73) Assignee: ADVANCED ENERGY INDUSTRIES, INC., Fort Collins, CO (US)

(21) Appl. No.: 12/891,576

(22) Filed: Sep. 27, 2010

(51) Int. Cl. H01L 27/088

(52) U.S. Cl. 257/379; 257/E27.06

(57) ABSTRACT

A semiconductor package for mounting multiple field effect transistors (FETs) is disclosed. The package includes a drain conductor between each FET's drain connection point and a drain terminal connector on the semiconductor package; a source conductor between each FET's source connection point and a source terminal connector of the source conductor on the semiconductor package, the source conductor containing the common inductance; a dielectric substantially overlaying said source conductor; a gate conductor on the dielectric substantially overlaying the source conductor; and said gate conductor, said dielectric and said source conductor forming a transformer, the transformer creating voltage in the gate conductor which almost exactly cancels voltage in said source conductor.

### FIELD OF THE INVENTION

This invention relates to a semiconductor package for high power transistors. More particularly the invention relates to a semiconductor package to combine multiple die such as metal oxide field effect transistors (MOSFETs) in high power high frequency applications.

### BACKGROUND OF THE INVENTION

The need for high power semiconductor devices has led to combining multiple die, such as field effect transistors (FETs) into a single package so that the multiple die act as if they are a single device. In high frequency applications parallel combinations of smaller FETs rather than one large FET maximize device performance and better control power dissipation. One example of a multiple-die semiconductor package is described in commonly-assigned U.S. Pat. No. 6,617,679 B2, entitled Semiconductor Package for Multiple High Power Transistors invented by Gideon Van Zyl and issued Sep. 9, 2003. An on-going goal with such multiple-die semiconductor packaging is the reduction of internal inductance in the conductive paths in the package. Problems with the internal inductance include power loss and oscillations within the package.

Inductance in the source conductive path of the semiconductor package is referred to as common because it is common to both a source-gate circuit path and a source-drain circuit path in the package. When high frequency source-drain current flows through the common inductance of the source conductive path, the source-drain current creates additional source voltage at the source of the FET. The additional source voltage at the source of the FET adds to the voltage of the gate drive and looks like the change in the FET threshold voltage. The additional source voltage changes during RF cycle. It may have one sign when current flows into the gate, and the opposite sign when current flows from the gate. As a result, power can flow between gate-source and drain-source circuits. Since the phase of the additional source voltage depends on the load, for some loads power can flow from gate driver into drain-source circuit, which may result in overloading the gate driver and insufficient amount of gate drive voltage. For some other loads, power can flow from the drain-source circuit into the gate-source circuit, which can make the whole FET unstable. Ideal FET should have absolute insulation (no power exchange) between gate and drain circuits.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

In accordance with this invention a semiconductor package for one or more high-frequency, high-power semiconductor die, such as MOSFETs or FETs, is constructed to cancel voltages due to the effect of a common inductance in the source conductor of the package. The common inductance is shared by a source-drain circuit path and a source-gate circuit path. The gate conductor and the source conductor separated by a dielectric layer are overlaid throughout a portion of the source conductor shared by both the source-drain circuit path and source-gate circuit path. Due to the inductance in the gate conductor and the common inductance in the source conductor, the source conductor, dielectric layer and the gate conductor form a transformer. The voltage at the source of the FET from the common inductance of the source conductor is matched at the gate of the FET by the voltage across the inductance in the gate conductor. In effect the gate voltage from the inductance in the gate conductor cancels out the source voltage from the common inductance in the source conductor thereby decoupling the source-gate circuit loop and the source-drain circuit loop.

The semiconductor package utilizes shortened, flat, wide conductive paths to reduce the inductance in the source conductor and the gate conductor. The source conductor has a split configuration with a central portion and a tail portion split into two arm portions. The central portion is a common path for both the source-gate circuit path and the source-drain circuit path in the package. One arm portion in the split tail contains inductance only in the source-gate circuit path. The other arm portion contains inductance only in the source-drain circuit path.

Further the gate conductor and the central portion of the source conductor are stacked with a dielectric layer between them to electrically separate them as they overlay each other. In such a structure, the inherent inductances in the overlaid conductors form a transformer. The voltage from the “common” inductance in the central portion of the source conductor appears at the source of the FET. Because of the transformer, substantially the same voltage from the gate inductance in the gate conductor appears at the gate of the FET. The voltages cancel each other out and the source-gate circuit loop is effectively decoupled from the source-drain circuit loop.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 is a top view of a layout of a multiple semiconductor package containing four field effect transistors (FETs);

FIG. 2 is a top view of a layout of a first layer of the semiconductor package of FIG. 1 containing the drain conductor, the source conductor, pads for soldering source connecting wires, and resistors between the pads and the source conductor;

FIG. 3 is a top view of a dielectric layer to be deposited on top of the source conductor of FIG. 2;

FIG. 4 is a top view of a gate conductor to be deposited on top of the dielectric layer of FIG. 3; and

FIG. 5 is an equivalent circuit diagram for the semiconductor package connected to one of the FETs and illustrates a source-gate circuit loop containing a high frequency driver external to the package and a source-drain circuit loop containing a DC power supply and a load circuit external to the package.

### DETAILED DESCRIPTION

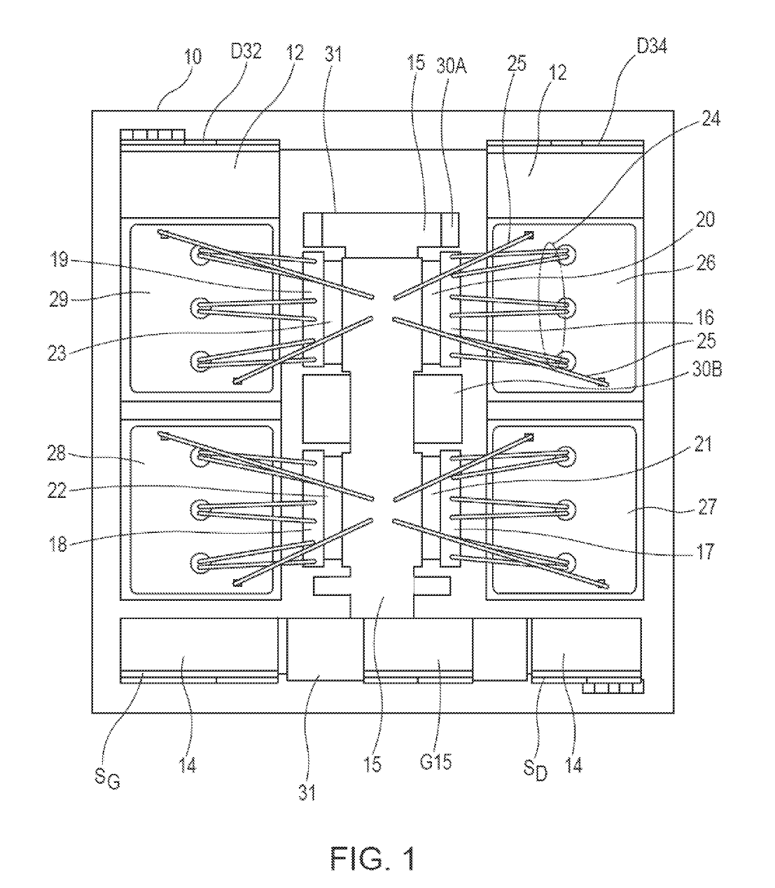

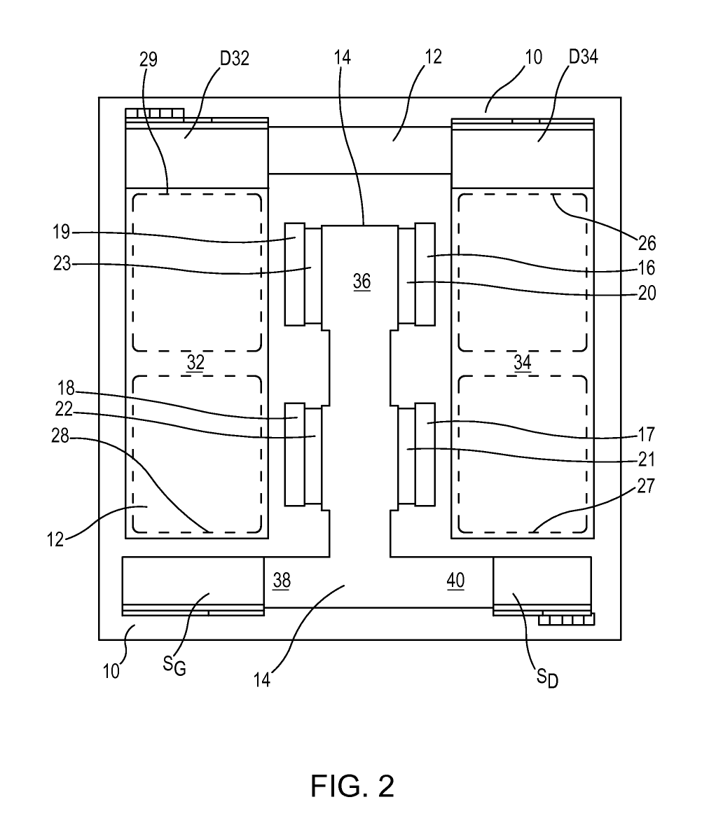

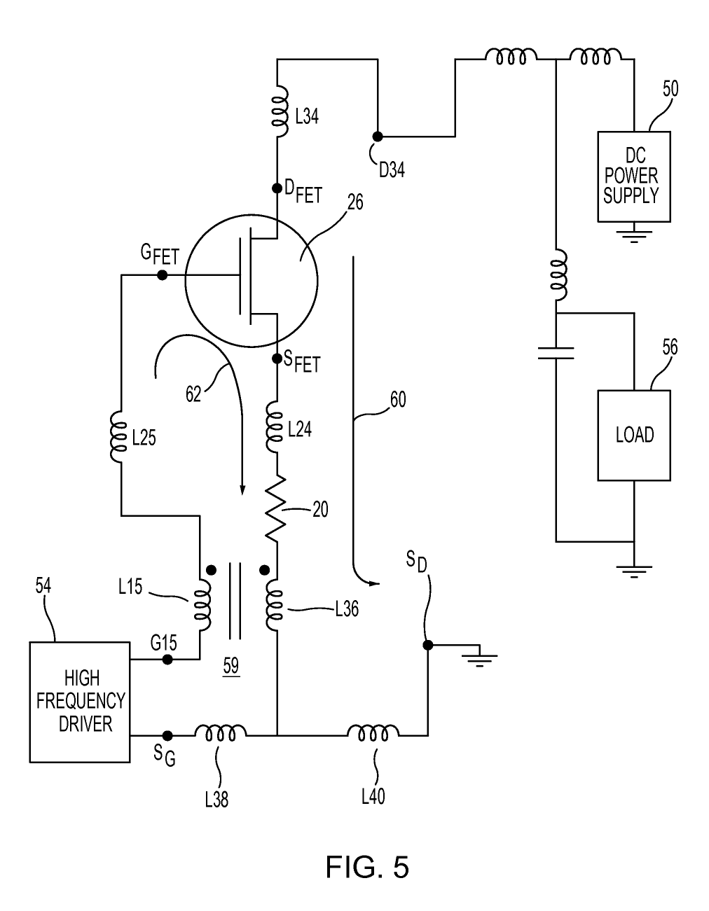

Referring now to the drawings, where like or similar elements are designated with identical reference numerals throughout the several figures, Now referring to FIGS. 1, 2 and 5, FIG. 1 is a drawing of a top view of a preferred embodiment of a semiconductor package containing four die 26, 27, 28 and 29 connected in parallel. The die are preferably FETs or MOSFETs which will be referred to as FETs herein. FIG. 2 shows the drain conductor 12 and the source conductor 14 to be connected to the FETs. FIG. 5 is an equivalent circuit diagram for the semiconductor package operating with FET 26 and having a high-frequency driver 54 attached between source-gate contact S_{G} and gate contact G15 and a DC power supply 50 and load 56 connected between source-drain contact S_{D} and drain contact D34. All of these contacts S_{G}, G15, S_{D} and D34 are at the edge of the semiconductor package in FIG. 1.

Source-drain circuit path 60 in the semiconductor package is made up of inductor L34, drain to source of FET 26, inductor L24, resistor 20 and inductor L36. Inductor L34 is the inductance in drain conductor 34, inductor L24 is the inductance of source wires 24, and inductor L36 is the “common” inductance of central portion 36 of source conductor 14 and acts as first coil L36 of transformer 59 in FIG. 5. Inductor L40 is the inductance in arm 40 of the split tail portion of source conductor 14.

Source-gate circuit path 62 in the semiconductor package is made up of inductor L15, inductor L25, gate-to-source capacitance in FET 26, inductor L24, resistor 20, inductor L36 and inductor L38. Inductor L15 is inductance of the gate conductor and is second coil L15 of transformer 59. Inductor L25 is the inductance of gate wires 25, and inductor L24 is the inductance in source wires 24. The source-gate current flow also passes through the common inductance L36 of central portion 36 of source conductor 14 which acts also as first coil L36 of transformer 59. Inductor L38 is the inductance in arm 38 of the split tail portion of source conductor 14.

Both circuit paths include inductor L36 which is therefore referred to as the common inductance in the source conductor. The source-gate circuit path also contains inductor L15 which is the second coil of transformer 59. Accordingly the voltage appearing across inductor L36, the common inductance, will be mirrored and appear across inductor L15. When there is a change in load 56, which load is typically a plasma chamber prone to large impedance changes, an accompanying large change in current will flow through common inductance of inductor L36. This produces a corresponding voltage change across inductor L36, which acts as first coil L36 of transformer 59. Whatever voltage change occurs at inductor L36 will appear at source S_{FET} of FET 26. Substantially the same voltage appears across inductor L15, the second coil of transformer 59 and thus at the gate G_{FET} of FET 26. This effectively decouples the source gate circuit loop 62 from the effects of load changes in source-drain circuit loop 60.

The semiconductor package of FIG. 1 is constructed on a ceramic substrate 10. Ceramic substrate 10 is a nonconductive material such as aluminum oxide, aluminum nitride, beryllium oxide, etc. The semiconductor package has drain conductor 12, source conductor 14 and gate conductor 15. The drain conductor 12 connects to the underside, or drain, of each FET; each FET drain is soldered to the drain conductor. The source conductor is connected to the source of each FET through resistors 20, 21, 22 or 23 by three pairs of wires. For example, three pairs of wires 24 connect between source conductive pad 16 and three source connections on FET 26. A pair of wires is used for each source connection to minimize inductance contributed by the wires. Resistors 20, 21, 22 and 23 are connected between source conductor 14 and source pads 16, 17, 18 and 19. The resistors assist simultaneous switching of the FETs 26, 27, 28 and 29.

Gate conductor 15 is connected to gate connections on the FETs by gate wires 25 soldered to the gate conductor 15 and to the gate connections on the FETs. For example, gate wires 25 connect the gate conductor 15 to gate connections on FET 26. Alternative connection locations on gate conductor 15 are provided for each FET by lateral extensions 30 of the gate conductor 15. For example, gate wires 25 for FET 26 could be soldered to lateral extensions 30A and 30B of the gate conductor 15.

Gate conductor 15 overlays source conductor 14 and is electrically separated from the source conductor by a dielectric layer 31. The dielectric layer is any depositable electrically insulative layer and is typically a glass layer. The dielectric layer 31 insulates the gate conductor and source conductor from each other. This stacked source conductor and gate conductor structure is particularly advantageous in the source-gate circuit loop. The inductances of the two conductors form a transformer with the two transformer inductances electrically positioned in the source-gate circuit loop to operate in voltage opposition to each other on opposite sides of the FET in the circuit loop. Therefore the voltage contribution of the “common” inductance (common to both the source-gate circuit loop and the source-drain circuit loop) in the source conductor cancels out the voltage contribution from the inductance inherent in the gate conductor.

The configuration of the conductive paths in the semiconductor package making up the drain conductor, the source conductor and the gate conductor is most clearly seen in FIGS. 2, 3 and 4 where each of the layers of the semiconductor package is shown. Referring now to FIGS. 1 and 2, a first metallization or conductive layer on the ceramic substrate 10 is deposited in patterns to provide drain conductor 12, source conductor 14, and source wire connection pads 16, 17, 18 and 19. Resistors 20, 21, 22 and 23 are deposited between the source conductor and source wire connection pads 16, 17, 18 and 19 respectively. The position of FETs 26, 27, 28 and 29 of FIG. 1 are shown in dashed lines in FIG. 2. The FETs are soldered to the drain after the drain conductor is deposited or after all layers of the semiconductive package have been deposited on the substrate 10.

The drain conductor 12 is as wide as, or slightly wider than the FET to be soldered to the drain conductor. Drain conductor 12 has two leg portions 32 and 34 to shorten the path to the FETs. Each leg 32 or 34 is made flat and wide to minimize the inductance of the drain conductor connected to each FET. The drain leg portions 32 and 34 are shown connected by a lateral portion of drain conductor 12 at the top of FIG. 2. Alternatively, a conductor external to the semiconductive package could replace lateral portion 33. Terminal connector D32 for leg 32 of drain conductor 12 is soldered or deposited at the top of leg 32 of drain conductor 12. Likewise terminal connector D34 for leg 34 of the drain conductor is soldered or deposited at the top of leg 34 of drain conductor 12.

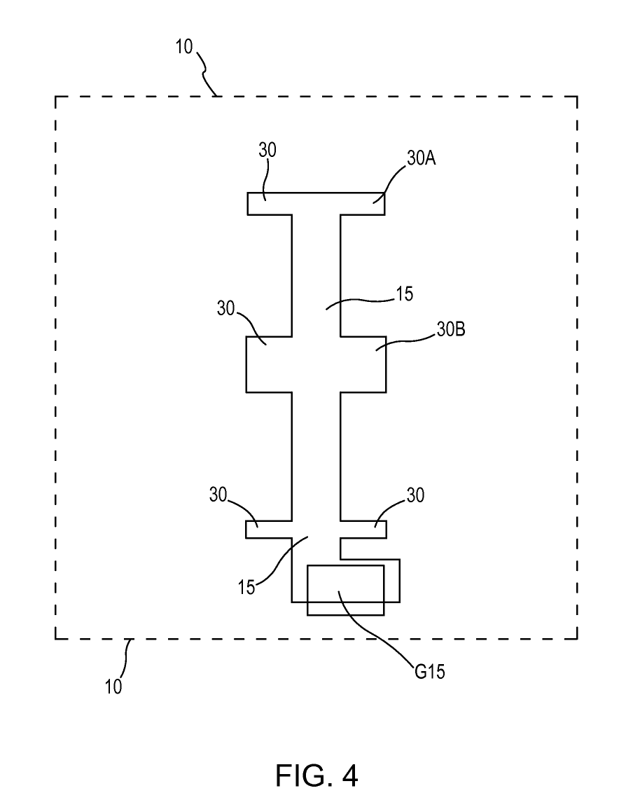

Source conductor 14, drain conductor 12 and gate conductor 15 (FIG. 4) are conductive metals, preferably gold or silver. In FIG. 2, source conductor 14 has a central portion 36 and a split tail portion with two arms 38 and 40. All portions of the source conductor are flat and wide to minimize inherent inductance in the conductive paths. In addition by splitting the tail of the source conductor, each FET source will see only the inductance of the central portion 36 and an inductance of one arm portion 38 or 40 of the source conductor. As described above, the central portion 36 of the source conductor contains the common inductance.

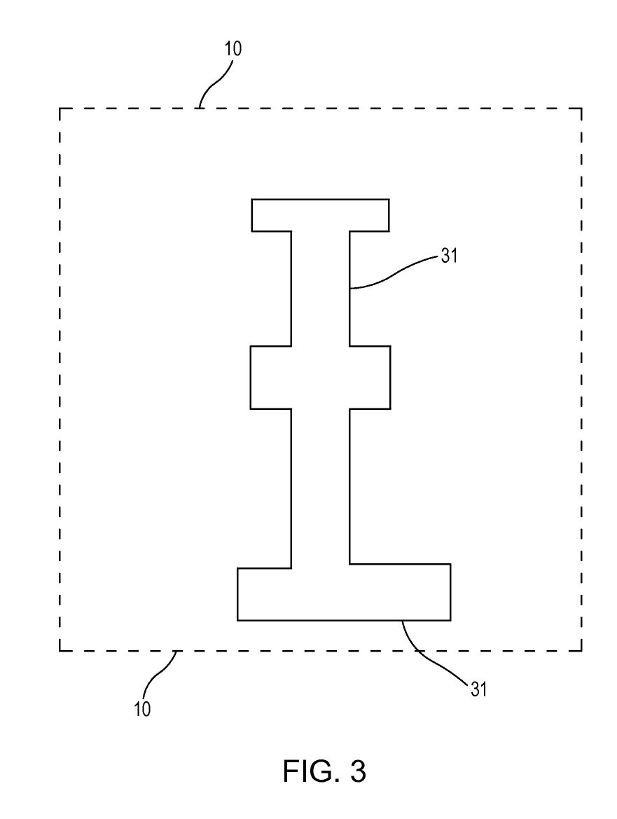

FIG. 3 shows the next layer deposited on the semiconductor package, which is a dielectric layer 31 positioned relative to the edge of the ceramic substrate 10 which is shown in dashed lines in FIG. 3. Referring to FIGS. 1, 2 and 3, the dielectric layer 31 is deposited on top of the source conductor 14. The dielectric layer overlays the central portion 36 of the source conductor 14 and a portion of arm 38 and arm 40 of source conductor 14. The dielectric overlay of portions of the arms 38 and 40 is done to provide a space for the gate conductor's terminal connector G15 (FIGS. 1 and 4).

The top layer deposited on the semiconductor package is the gate conductor 15 shown in FIG. 4 positioned relative to the edge of the ceramic substrate 10 whose position is shown in dashed lines. Referring to FIGS. 1, 2, 3 and 4, the gate conductor 15 is deposited on top of the dielectric layer 31. The gate conductor 15 and the dielectric layer 31 overlay substantially all the central portion 36 of the source conductor 14. Terminal connector G15 provides the external connection for gate conductor 15 and is soldered to, or deposited on, that conductor. The gate conductor is short, flat and wide to minimize its inductance when carrying the driving signal to the gate of an FET.

The source and gate conductors separated by the dielectric layer are stacked on top of each other. To the extent the source and gate conductors are stacked on top of each other, the configuration forms a transformer structure represented as transformer 59 in the equivalent circuit of FIG. 5. As described above, the common inductance of the source conductor 14 throughout its central portion 36 interacts with the inductance of the gate conductor 15 to form the transformer. When a high frequency driver is connected between the source conductor 14 and the gate conductor 15, the transformer effect of the stacked source and gate conductors will cancel out the voltage at the FET due to the common inductance of the source conductor.

FIG. 5 is a diagram of an equivalent circuit of the semiconductor package portion for FET 26 along with a DC power supply 50, a high-frequency driver 52 and a load circuit 56. DC power supply 50 provides power for FET 26 and is connected between drain conductor terminal connector D34 (FIG. 1) and source conductor terminal connector S_{D} (FIGS. 1 and 2). High frequency driver 52 provides the high-frequency, or radio-frequency (RF), drive to switch the gate of FET 26 on and off. High frequency driver 52 is connected between source-gate conductor terminal connector S_{G} (FIGS. 1 and 2) and gate conductor terminal connector G15 (FIGS. 1 and 4). Load 56 is connected between drain conductor terminal connector D34 and source conductor terminal connector S_{D}. The operation of the equivalent circuit in FIG. 5 is described above with reference to FIGS. 1 and 5 at the beginning of the detailed description.

It will be appreciated by one skilled in the art that a number of embodiment changes could be made without departing from the spirit and scope of the invention. For example the gate conductor might be deposited first and the dielectric layer and source conductor could be deposited on top of the gate conductor to create the transformer. In another variation contemplated for the invention the source conductor might not have a split tail so that the common inductance is the only inherent inductance in the source conductor.

In conclusion, the present invention provides, among other things, a semiconductor package for high-frequency multiple-transistors and a method for configuring such a semiconductor package to decouple of common inductance shared by a source-gate circuit loop and a source-drain circuit loop in the package. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A semiconductor package on a nonconductive substrate for mounting multiple field effect transistors (FETs) connected in parallel by conductors configured to minimize the effect of common inductance shared by both a source-gate circuit and a source-drain circuit of the semiconductor package for each FET, said package comprising:
a drain conductor between each FET's drain connection point and a drain terminal connector on the semiconductor package;
a source conductor between each FET's source connection point and a source terminal connector of the source conductor on the semiconductor package, the source conductor containing the common inductance;
a dielectric substantially overlaying said source conductor;
a gate conductor on the dielectric substantially overlaying the source conductor; and
said gate conductor, said dielectric and said source conductor forming a transformer, the transformer creating voltage in the gate conductor which almost exactly cancels voltage in said source conductor.

2. The semiconductor package of claim 1 wherein;
said drain conductor is deposited on a nonconductive substrate of the package and configured to minimize the inductance of the drain conductor; and
said source conductor is deposited on the nonconductive substrate of the package and configured to minimize the inductance of said source conductor; and
said gate conductor is deposited on the dielectric and is configured to minimize the inductance of said gate conductor.

3. The semiconductor package of claim 2 wherein said source conductor has a central portion containing the common inductance and a split tail portion, the split tail portion having a first arm from the central portion to a source-gate terminal connector on the semiconductor package and a second arm from the central portion to a source-drain terminal connector on the semiconductor package.

4. The semiconductor package of claim 3 wherein:
said gate conductor overlays the central portion of the source conductor; and
the transformer cancels voltage from the common inductance in the central portion of said source conductor.

5. A semiconductor package having multiple FETs (Field Effect Transistors) connected in parallel to act as a single FET, said semiconductor package comprising:
a source conductor having a central portion and a tail portion split into two arms; the central portion of the source conductor is a common conductive path for both a source-gate circuit loop and a source-drain circuit loop; one arm in the tail portion in the source-gate circuit loop of the semiconductor package, and the other arm in the tail portion in the source-drain circuit loop;
a gate conductor stacked on the central portion of the source conductor with a dielectric layer between the conductors to electrically insulate them as they overlay each other;
a transformer formed by a first inherent inductance in the central portion of the source conductor and a second inherent inductance in gate conductor stacked on the central portion of the source conductor;
the first inductance of said transformer passing a first voltage through the central portion of the source conductor to the source of each FET; and
the second inductance of said transformer passing a second voltage through the gate conductor to the gate of the FET, and the first and second voltages being substantially the same whereby the voltages cancel each other out, and the source-gate circuit loop is effectively decoupled from the source-drain circuit loop.

6. The semiconductor package of claim 5 comprising in addition:
a drain conductor in the source-drain circuit loop connected to the drain of each FET.

7. The semiconductor package of claim 6 wherein the drain conductor and the source conductor are deposited on a ceramic substrate of the semiconductor package.

8. The semiconductor package of claim 8 wherein the dielectric layer is deposited on at least the central portion of the source conductor.

9. The semiconductor package of claim 8 wherein the gate conductor is deposited on the dielectric layer and overlays the central portion of the source conductor whereby the transformer is formed by the gate conductor stacked over the central portion of the source conductor.

10. A semiconductor package electrically connecting to at least one semiconductor die mounted on the package, said semiconductor package configured to cancel the effect of a common inductance shared by a first circuit path in the package to the die and a second circuit path in the package to the die, and said package comprising:
a first electrical conductor on a nonconductive layer of the package, the first electrical conductor containing the common inductance shared by the first circuit path and the second circuit path;
a dielectric layer covering the first electrical conductor;
a second electrical conductor on the dielectric layer and stacked over the first electrical conductor, the second electrical conductor containing a second inductance;
said first electrical conductor responsive to a direct current power supply when attached to the package in the first circuit path to supply electrical power to a load in the first circuit path;
said second electrical conductor responsive to a high frequency driver when attached to the package to drive a high frequency electrical signal through the second electrical conductor in the second circuit path with the die to control the power delivered to the load in the first circuit path whereby at high frequency the common inductance in the first electrical conductor and the second inductance in the second electrical conductor act together as a transformer so that voltages from the inductances are applied in opposition at the die to cancel each other out.

11. The semiconductor package of claim 10 wherein the die is a field effect transistor and the first electrical conductor connects to the source of the field effect transistor and the second electrical conductor connects to the gate of the field effect transistor.

12. The semiconductor package of claim 10 wherein said first electrical conductor has a central portion with a conductive path containing the common inductance and a split tail portion with two arms, one of the arms having a conductive path with an inductance in the first circuit path and the other arm having a conductive path with an inductance in the second circuit path.

13. The semiconductor package of claim 12 where said second electrical conductor overlays substantially all the central portion of the said first electrical conductor.

14. The semiconductor package of claim 13 wherein:
the die is a field effect transistor;
the central portion of the first electrical conductor connects to the source of the field effect transistor;
the second electrical conductor connects to the gate of the field effect transistor; and
the first circuit path is a source-drain circuit path and the second circuit path is a source-gate circuit path.
